(19) United States
(12) Patent Application Publication
(10) Pub. No.: US 2003/0025533 A1
(43) Pub. Date: Feb. 6, 2003

(54) Multi-input differential circuit

(76) Inventors: Shin-ichi Akita, Toshima-ku (JP); Yasuhide Ikura, Toshima-ku (JP); Tatsuhiro Yano, Toshima-ku (JP)

Correspondence Address: HOGAN & HARTSON L.L.P., 500 S. GRAND AVENUE, SUITE 1900, LOS ANGELES, CA, 90071-2611, US

(21) Appl. No.: 10/179,458

(22) Filed: Jun. 24, 2002

(30) Foreign Application Priority Data
Jun. 25, 2001 (JP) 2001-192046

(51) Int. Cl. H03K 5/22

(52) U.S. Cl. 327/71

(57) ABSTRACT

The invention provides a NANO-ampere operable differential circuit by means of a few additional components. The multi-input differential circuit consists of more than three input elements that are connected to the same tail node, and an adaptive bias current control circuit. Applications of this multi-input differential circuit, which are, for instance comparators and voltage followers, do have a very low operation current at a normal operation mode. The proposed differential circuit is applicable for all kinds of analog complex circuits to attain nano-power operation.

### BACKGROUND OF THE INVENTION

The present invention relates to an over-three multi-input differential amplifier with adaptively controlled biasing.

1. Description of the Related Art

Not only handy equipment but also every kind of electric equipment incorporates a voltage comparator circuit or differential amplifier applied for low voltage detection or battery charge-discharge control or signal buffering. It is assumed that a few billion of such equipments are in use worldwide. If one comparator circuit draws 10 μA for example, the total idling current is multiplied by 10 billion sets and 10,000 ampere is given. If an operation voltage is assumed at 5 volt, the total power consumption reaches 50 KILO-watt what is equivalent to one power plant capacity. The present invention will reduce current consumption of a voltage comparator and differential amplifier drastically to contribute to energy saving on a global scale.

2. Description of the Prior Art

FIG. 18 shows a conventional prior differential circuit diagram applied for voltage comparator circuit. A differential circuit is composed of MP1, MP2, MP3, MN2 and MN3; a buffer circuit is composed of MP5 and MN5. A current source Ib and a N-FET MNB form a bias current generator. A reference voltage is fed to the Vref input terminal of the voltage comparator circuit. FIG. 19 shows simulated operation waveforms of the prior differential circuits in FIG. 18. When the input signal p is lower or higher than the reference input Vref sufficiently, the differential circuit and the buffer circuit draw constant idling current. The relationship between the idling current and rise-fall time or transition time of the output can be derived from the charge equation Q=CV roughly. As shown in FIG. 18, Id stands for the drain current of MP2; Vg for the voltage transition at OUTX; dT1 for the transition time of Vg; Ig for the charge or discharge current of Cg during dT1, then equation (1) is given as,

Ig*dT1=Cg*Vg (1)

Since Ig is a breeding current of Id, the value is supposed as ⅕ to 1/20 generally. Letting the breeding factor K,

Ig=Id/K

Only a part of dT1 contributes to the delay time of output OUTX, it is assumed that around 80% of dT1 occupies the delay time by evaluation from the relation between the threshold voltage and supply voltage.

T1=0.8*dT1=0.8*K*(Cg*Vg)/Id (1)

“dT2” stands for the transition time of OUTX; Ic for idling current of MP5; all of Id flows into CL when MN5 is off state, then following equation is derived.

dT2=(CL*Vdd)/Ic

The delay time T2 is measured at the half position of supply voltage, then

T2=0.5*dT2

Letting a required delay specification be Tos,

Tos<T1+T2

Id>0.8*K*Cg*Vg/T1 (2)

Ic>0.5*CL*Vdd/T2 (3)

At the rise transition the load capacitor CL is charged from MN5 and the idling current of MP5 does not contribute to transition time. Then the delay at the rise transition equals with sum of dT1 and dT3. Since the gate of MN5 is biased forward sufficiently at the rising transition of OUTX usually, the delay dT3 is fairly smaller than dT1. However when the idling current Id is set to very little level, it should be noted that the total delay time becomes very large number.

The idling current of whole circuit Ii is given as,

Ii=2*Id+Ic

The drain current “Id” is multiplied with 2 because Id is the idling current of one side of differential circuit.

For example, T1<20 μS, T2<5 μS, Cg=0.1 pF, CL=50 pF, Vg=2V, Vdd=3V, K=20,

Ii>19.8 μA

In case of, T1<5 μS and T2<2 μS

Ii>61.5 μA

In this way, the minimum idling current can be evaluated by a required specification for output delay time.

FIG. 19 shows simulated waveforms of the circuit in FIG. 18 when the input p is raised slowly from ground level to VDD level and then falls to ground level again. Even though the transition is very slow as few hundreds hours in an actual voltage detector application, the simulation time scale is accelerated for easy observation. “co” indicates the output waveform of prior comparator circuit when the bias current is designed to meet the required delay time less than 24 μS. “qo” indicates the output waveforms of prior circuit shown in FIG. 18 in which the bias current is limited below 200 nA. The delay time at rise or fall transition is 59 μS, 728 μS respectively, those delay time are fairly large and not suitable for general applications.

A voltage follower circuit is also popular application of a differential amplifier and useful for measurement circuit condition of a differential amplifier. FIG. 20 shows a voltage follower circuit diagram modified from the connection in FIG. 18. The configuration of differential circuit part is same as the circuit in FIG. 18; the output is connected with the m input to form a voltage follower amplifier with unity gain. The output waveform follows identically with the p input signal ideally. FIG. 21 is a simulated waveform diagram of the circuit in FIG. 20. A denoted “co” shows a waveform of the output when a sufficient idling current is supplied, measured to be 11.6 μA shown as “vvdco”. The denoted “qo” shows a waveform when the idling current is limited to low level such as 588 nA. The waveform of “co” follows with the p input signal roughly and the delay time is 27 μS. However “qo” has big delay 335 μS and dull transition waveform. A voltage follower application also sacrifices operation speed unless enough idling current is supplied to the differential circuit that is backed by previous equation (2) and (3).

In the prior art, the idling current cannot be reduced from the certain limitation decided by a required transition delay time of the output. If it is set to lower current than the limitation, the transition delay time becomes very large and that will result in application problems. The order of microampere looks like negligible small in the aspect of total system current consumption, however the accumulated amount becomes huge value because multi-billion of equipments are in work on the global scale. It should be noted that reducing the idling current of a voltage comparator and differential amplifier incorporated in all of electric equipments is a significant subject for global energy saving.

### SUMMARY OF THE INVENTION

As described previously, it is impossible to reduce the idling current by means of prior circuit and design methodology such as the circuits in FIG. 18. The presented invention provides a means composing of small count of transistors and a design methodology proofed sufficiently by a formula well correlated with measured results.

To solve the above problems, a new circuit configuration and a new design theory is proposed, in which the idling current can be designed on the order of NANO-ampere when the inputs are far away from a detective reference level, and only at the detection transition the operation current becomes required level to attain a specified transition delay time. It is well known that output transition time of the voltage comparator circuit relates to operation current. Therefore it is presumable that boosted operation current only at the detection transition will realize low power and high-speed circuit, however no prior proposal attains the goal with less transistor count and simple design theory. The invention presented that a new means and a method realize the current boost only at the output transition, by a combination of cascaded transistor architecture and conventional differential circuits of which transistor pairs are designed under a new theory.

### BRIEF DESCRIPTION OF THE DRAWINGS

FIG. 1 is a circuit diagram showing an embodiment of the present invention.

FIG. 2 is a transfer characteristic of circuit shown in FIG. 1 indicating an optimum operating condition claimed.

FIG. 3 is a transfer characteristic of circuit shown in FIG. 1 indicating an improper operating.

FIG. 4 is a circuit diagram showing an embodiment of the present invention as a voltage comparator application.

FIG. 5 is a simulation waveform diagram showing voltages and currents of respective node the circuit shown in FIG. 4.

FIG. 6 is a circuit diagram showing an embodiment of the present invention as a voltage comparator application.

FIG. 7 is a simulation waveform diagram showing voltages and currents of respective node the circuit shown in FIG. 6.

FIG. 8 is a circuit diagram showing an embodiment of the present invention as a voltage comparator application.

FIG. 9 is a transfer characteristic of circuit shown in FIG. 8.

FIG. 10 is a simulation waveform diagram showing voltages and currents of respective node the circuit shown in FIG. 8.

FIG. 11 is a circuit diagram showing an embodiment of the present invention as a voltage comparator application.

FIG. 12 is a simulation waveform diagram showing voltages and currents of respective node the circuit shown in FIG. 11.

FIG. 13 is a circuit diagram showing an embodiment of the present invention as a voltage comparator application.

FIG. 14 is a transfer characteristic of circuit shown in FIG. 13.

FIG. 15 is a simulation waveform diagram showing voltages and currents of respective node the circuit shown in FIG. 13.

FIG. 16 is a circuit diagram showing an embodiment of the present invention as a voltage comparator application.

FIG. 17 is a circuit diagram showing an embodiment of the present invention as a voltage comparator application.

FIG. 18 is a conventional differential amplifier for voltage comparator application.

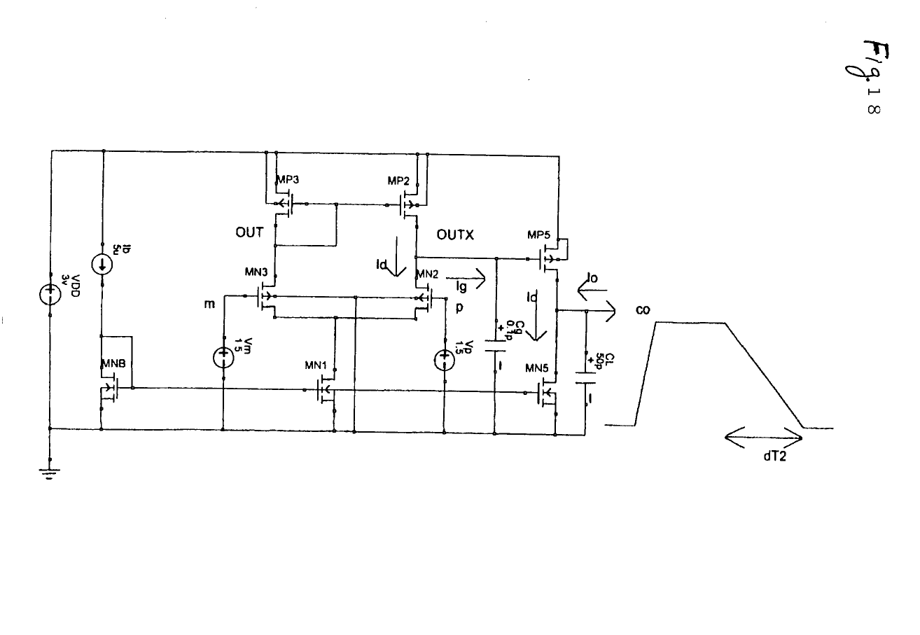

FIG. 19 is a simulation waveform diagram showing voltages and currents of respective node the circuit shown in FIG. 18.

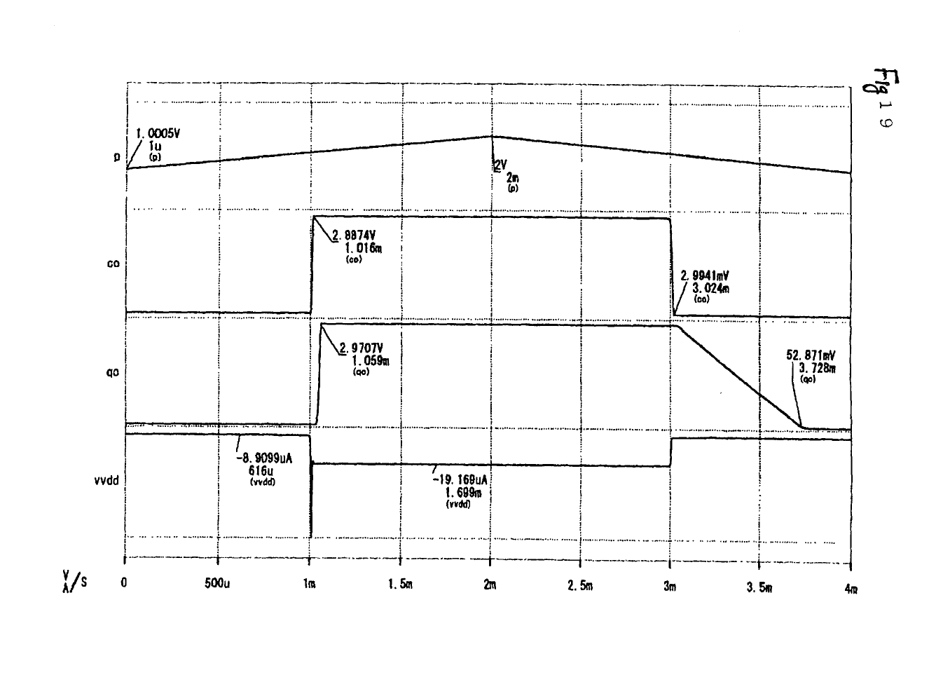

FIG. 20 is a conventional differential amplifier for voltage follower application.

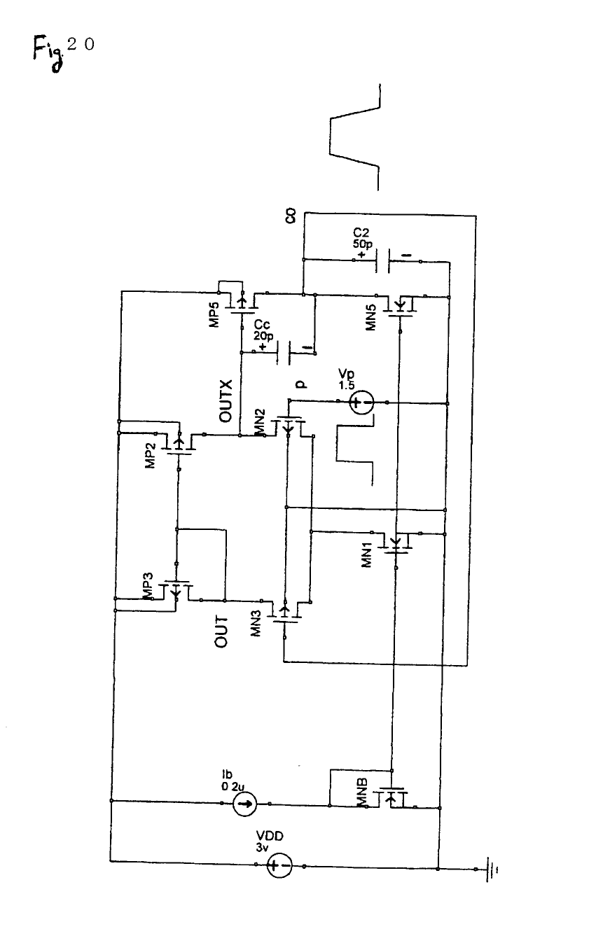

FIG. 21 is a simulation waveform diagram showing voltages and currents of respective node the circuit shown in FIG. 20.

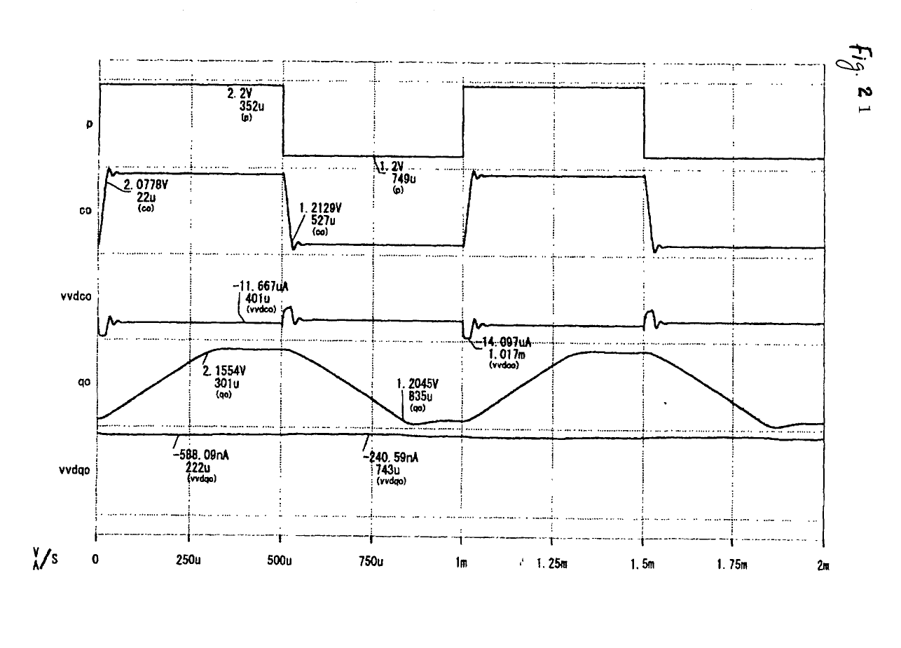

FIG. 22 is a circuit diagram showing an embodiment of the present invention as a voltage follower application.

FIG. 23 is a transfer characteristic of circuit shown in FIG. 22.

FIG. 24 is a simulation waveform diagram showing voltages and currents of respective node the circuit shown in FIG. 23.

FIG. 25 is a circuit diagram showing an embodiment of the present invention as a voltage follower application.

FIG. 26 is a simulation waveform diagram showing voltages and currents of respective node the circuit shown in FIG. 25.

FIG. 27 is a circuit diagram showing an embodiment of the present invention as a voltage follower application.

FIG. 28 is a simulation waveform diagram showing voltages and currents of respective node the circuit shown in FIG. 27.

FIG. 29 is a circuit diagram showing an embodiment of the present invention as a voltage follower application.

FIG. 30 is a circuit diagram showing an embodiment of the present invention as a voltage comparator application.

### DETAILED DESCRIPTION

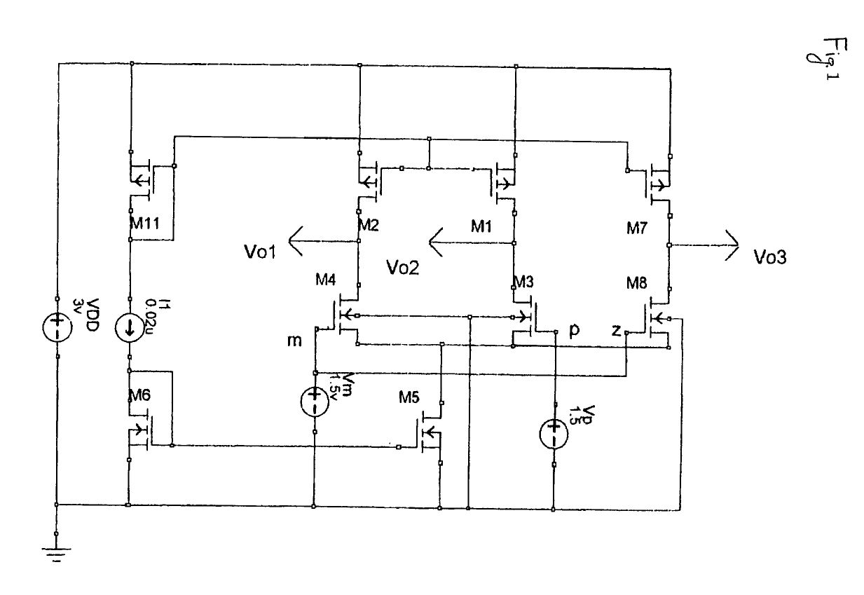

FIG. 1 is a circuit diagram showing an embodiment of the present invention corresponding to the claim-1. M3, M4, M5 and M8 are N-FET. M5 forms a bias current control circuit and is connected to three of input means M3, M4, M8. P-FET M1, M2, and M7 are three load means and connected to the said input means. Each load means forms a current mirror coupled with P-FET M11 in the bias current generation circuit and is controlled under constant current as soon as possible. Therefore it is regarded as a current source and works as a high impedance load device in an amplifier.

Each of M1 and M3, M2 and M4, M7 and M8 constitutes an amplifier. Three amplifiers are connected to the bias current control circuit M5 through a common node called tail node. An inverting threshold of each amplifier can be calculated from a well-known source-drain current equation of FET roughly. Focusing on the amplifier composed of M1 and M3.

Id stands for drain current of M3,

Id=0.5*Gm(Vg−Vtn)(Vg−Vtn)(1+Lamda*Vds) (5)

Where Gm is the conductance of M3, Vtn is the threshold voltage, Vg is the input voltage, Lamda is the channel length modulation factor, and Vds is the source drain voltage.

Being assumed that the inverting threshold of amplifier VT is defined as the source drain voltage of M1 and M3 is identical each other,

VT={SQR(Id/0.5*Gm)+Vtn}/SQR(1+Lamda*Vds)+Vs (6)

Vds=(Vdd−Vs)/2

Gm=(½)*u*Cox*(W/L)

Where Vs is the voltage level at the tail node, μ is the mobility of carrier; Cox is the gate oxide capacitance per unit area. Equation (6) indicates that the inverting threshold depends upon Gm namely FET size (W/L) since other parameter is constant value. Id flows both of M1 and M3, the size ratio between M1 and M3 decide the inverting threshold. It is not contradict against well-known formula. Thus the inverting threshold of assumed single amplifier is simply expressed. In case of two input differential circuit, the inverting threshold can be also expressed by similar prior formula. However a more-than three multi-input differential amplifier does not have such an established design theory or methodology. The reason why is no inevitable market needs for a more-than three multi-input differential amplifier so far. The presented patent has discovered the validity of the multi-input amplifier in adaptive biasing circuit application and thereby the examples of embodiment describe the qualitative analysis and show the variety of applications.

Embodyment

In FIG. 1, the bias current control circuit M5 has important roll. It is not restricted one component; more parts form it as described later. The present invention disclose that three amplifiers act each other in the range of the size of M5 or the mirror current of bias current control circuit and a boundary condition is discovered successfully.

Hereinafter, a total sum of FET means a summing size of FETs connected in parallel way.

And a theoretical mirror current means a mirrored current under no obstacle to mirror operation. Usually the mirror current is proportional to transistor size.

In the figure when the size of M5 is larger than the sum of FET size M1, M2 and M7 or the theoretical mirror current of the bias current control circuit is larger than the total sum of mirror current of M1, M2 and M7, the circuit in FIG. 1 is not functional. The tail node is shorted to ground level; the three amplifiers have no interaction each other.

When the theoretical mirror current of the bias current control circuit is smaller than total sum of mirror current of M1, M2 and M7, three amplifiers begin interaction each other. Since the total sum of mirror current of M1, M2 and M7 is limited under the mirror current primarily to be flowed, borrowing and lending of current among three amplifiers is caused to generate large voltage swing at output node. A large voltage swing at the output node is generated by borrowed or lent current change because the operation point of each three input-FET is just located on the threshold edge and even small drain current modulation produces large drain voltage deflection.

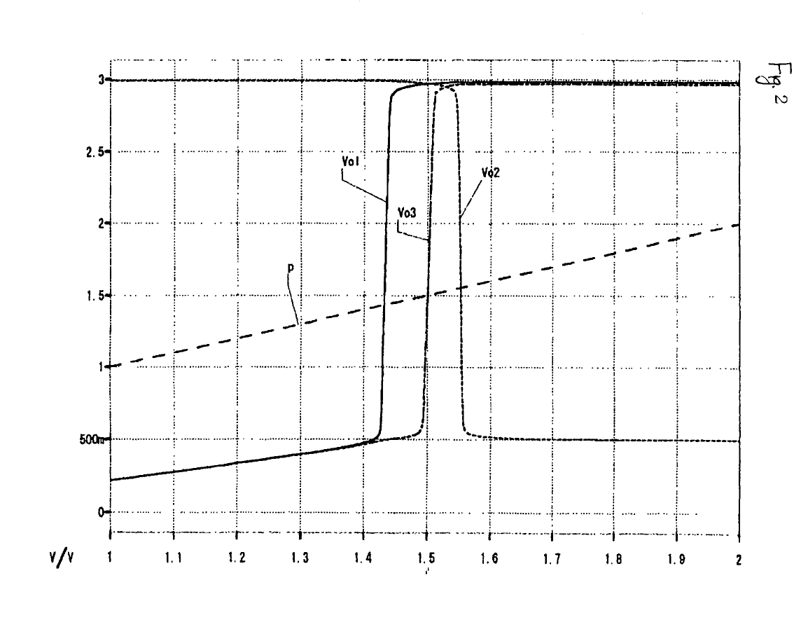

FIG. 2 is a transfer characteristic of the circuit shown in FIG. 1 indicating an optimum operating condition. As shown in FIG. 1 the input of M3 is connected to the input signal Vp, and a reference voltage is fed to the input of M4 and M8. Due to three inputs, there are many combinations of input connection; a simple connection for transfer curve is adopted for easy understanding. In FIG. 2 the outputs Vo1 and Vo2 are offset from the reference input Vm 1.5V. The output Vo1 changes from low to high at Vp=1.43V. It is called as theoretical offset, −70 mV in this case. The theoretical offset is not caused from a production deviation but designed intentionally. The output Vo2 has +50 mV theoretical offset

The characteristic like shown in FIG. 2 are produced by following method.

The size of load FET M1, M2, M7 or the size of input FET M4, M3, M8 must meet with the below conditions,

Vp=Vm, Vm=1.5V, Id1<<Id3 and Id2<<Id3,

And Id3=17 nA, and VT3=1.5V and Equation (6).

Where Id1, Id2, Id3 is the drain current of M4, M3, M8 respectively. VT3 is inverting threshold of the output Vo3. The reason why being put Id3=17 nA is that the current source in the bias current generator is 20 nA and M7 is mirrored with ration of 1 to 0.85.

In case of FIG. 2, the size (W/L) of M1, M2, M7, M5 is given as 1.1, 1.1, 0.85, and 2.5 respectively.

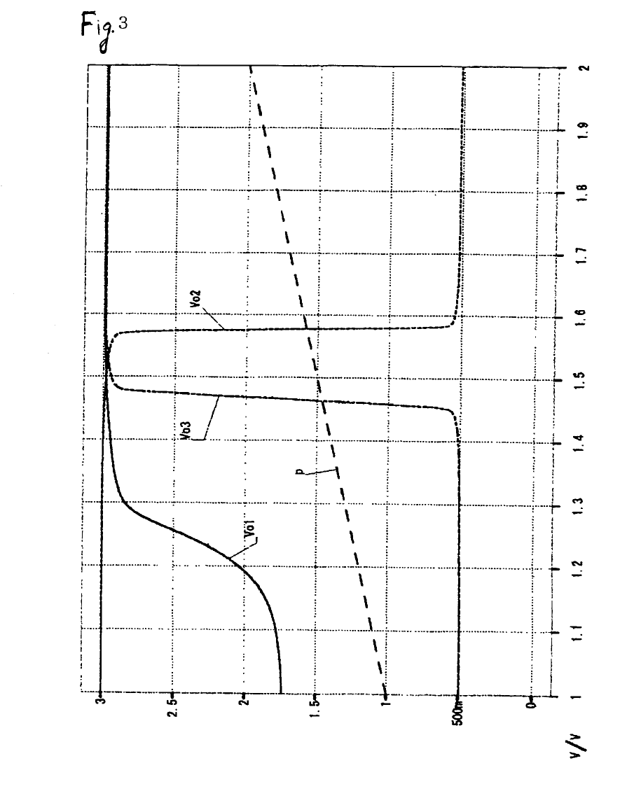

When the size of M5 is smaller than the sum of FET size M2 and M7 or the theoretical mirror current of the bias current controller is smaller than sum of mirror current of M2 and M7, the circuit in FIG. 1 begins a misconduct operation. Decreasing the size of M5, the potential of tail node or M4 source node goes up and it results in degradation of input voltage range of M4. In the end, M4 cannot draw an enough current from M2 to output a low level. As shown in FIG. 3, the denoted vo1 is floated over the low level, which is reached by the denoted vo2 or vo3. Therefore one of boundary condition is that the theoretical mirror current of the bias current control circuit is smaller than the total sum of mirror current of M1, M2 and M7. And the other side is that the theoretical mirror current of the bias current controller is lager than the sum of mirror current of two load FET of three load FET, excluding largest one in the size. Even though it is called “boundary”, it is not digital condition since the drain current of FET is not discontinuous even around the threshold voltage.

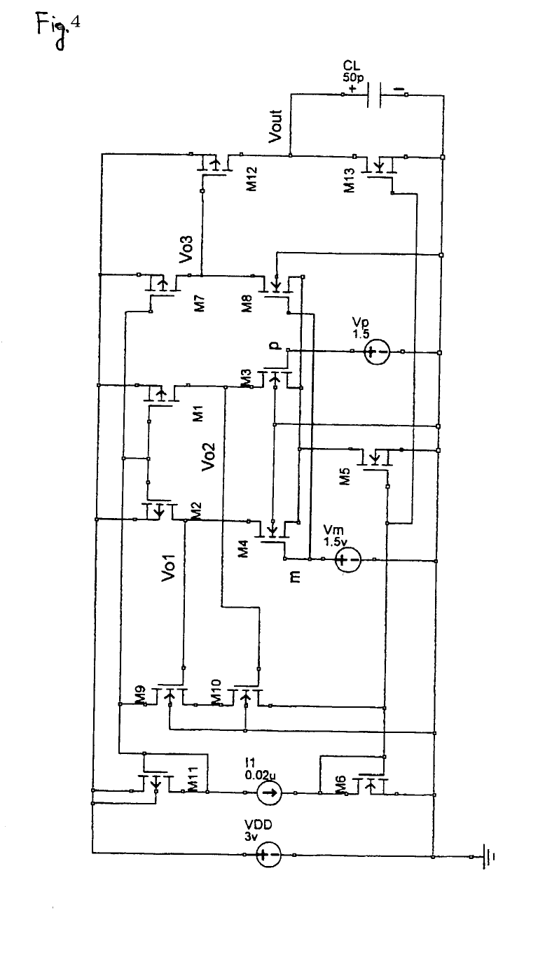

FIG. 4 is a circuit diagram showing a second embodiment of the present invention corresponding to the claim-1 and 2. It is applied as a voltage comparator of which bias current is controlled or increased adaptively. P-channel FET M1, M2, M7 and N-channel FET M3, M4, M5, M8 and M6 have same connections as FIG. 1. Two N-channel FET M9 and M10 compose a current conversion circuit are connected to the output vo1 having minus offset and the output vo2 having plus offset. Both of vo1 and vo2 is at high state, the current conversion circuit flows a current through the bias current generation circuit and then increase a current in the bias current control circuit M5 by positive feedback. N-FET M13 and P-FET M12 compose an output buffer that is connected to the output vo3 having no offset.

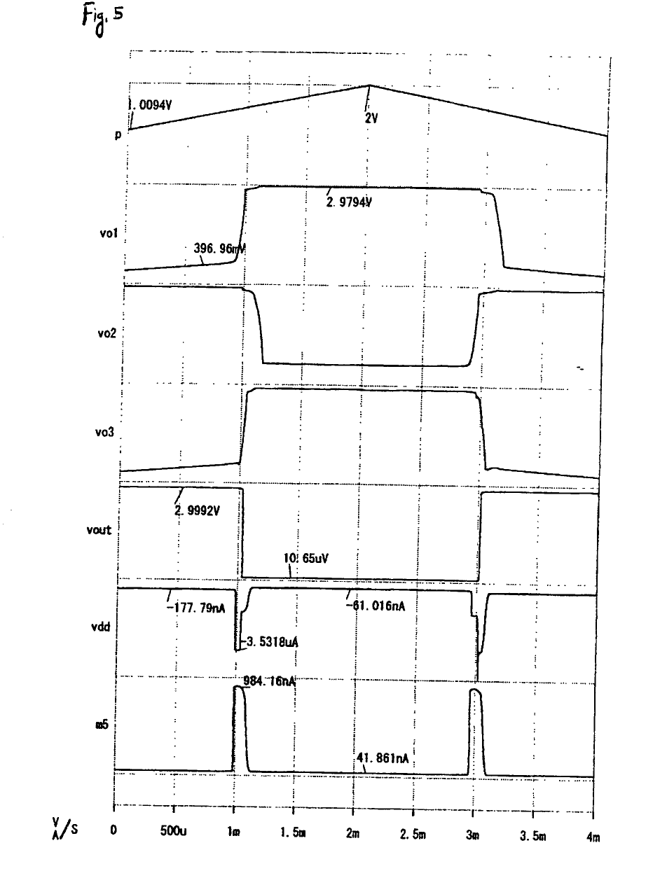

FIG. 5 is a simulated waveform diagram showing voltages and currents in respect to the circuit in FIG. 4 as a voltage comparator.

In the figure, a time scale is plotted on the horizontal axis and the number at pointing line indicates voltage or current. In case shown FIG. 5, VDD=3V, CL=50 pF, a constant voltage as VDD/2 is fed to the m input as a reference input and at the p input terminal a slowly changing triangular signal is fed. The voltage waveform of the output terminal Vo1, Vo2, Vo3 and Vout are shown by “vo1”, “vo2”, “vo3” and “vout” respectively, the current waveform of the voltage supply Vdd and the FET M5 are shown by “vdd” and “m5”.

The p input is approaching to the reference voltage, both of the output vo1 and vo2 turn to high level so that M9 and M10 turn on to flow a current and the bias current control circuit increases current from 41 nA to 984 nA and then the whole circuit become activated. With the exception of this activated status, the whole circuit is operated under very low current consumption, and the supply current vdd is measured to be 177 nA or 61 nA. The output delay time is 41 μS at the fall transition, 21 μS at the rise transition that is fairy improved from the prior example 728 μS at fall and 59 μS at rise.

A reference U.S. Pat. No. 4,690,391 has proposed similar circuit configuration as the present invention in FIG. 1 or FIG. 4. However, it is obvious that the referenced circuit has different operation mechanism and function. Because all of its output have theoretical zero offset, and the important relationship between a bias current and total sum of mirror current is not disclosed, and moreover the propose circuit concept never intend to apply for adaptive control by positive feed back current. Even though the present invention has similar circuit configuration as the referenced USP, it must be stressed that its essence, effectiveness, and claims are quite different.

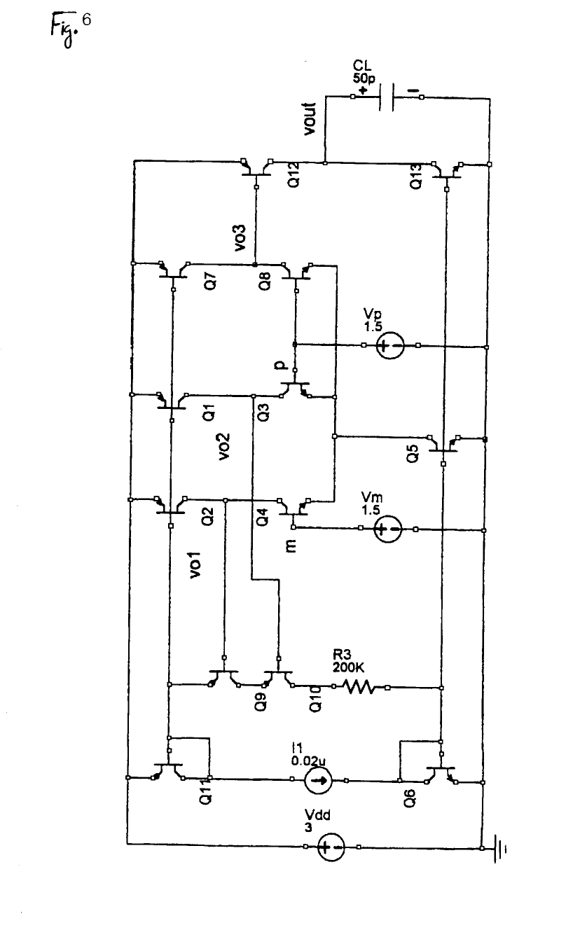

FIG. 6 is a circuit diagram showing a third embodiment of the present invention applied for a bipolar process or a silicon germanium process, corresponding to the claim-1 same as FIG. 4. PNP transistors Q1, Q2, Q7 and NPN transistors Q3, Q4, Q5, Q8 compose a three input differential amplifier. PNP transistor Q9, Q10 and resistor R3 compose a current conversion circuit. PNP transistor Q11, NPN transistor Q6 and a current source I1 form a bias current generator. A very high resistor or a transistor connected with fixed base potential can replace the current source I1. A bias current control circuit comprises of transistor Q5 as the simplest case.

The output vo1 having minus offset and the output vo2 having plus offset are over the forward potential Vbe, the current conversion circuit draws a current through the bias current generation circuit and then increase a current in the bias current control circuit Q5 by the positive feedback. NPN transistor Q13 and PNP transistor Q12 compose an output buffer that is connected to the output vo3 having no offset.

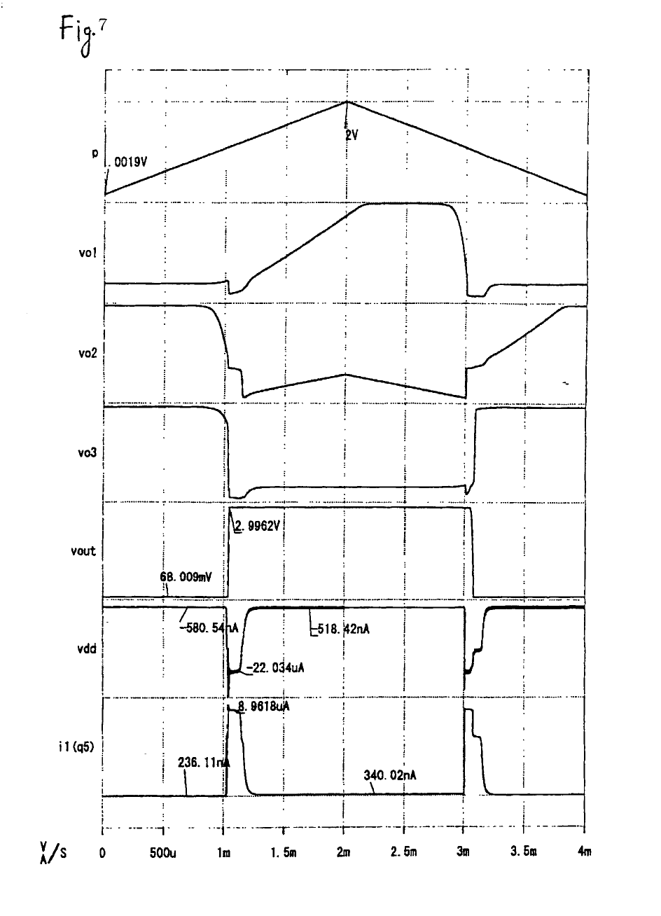

FIG. 7 is a simulated waveform diagram showing voltages and currents in respect to the circuit in FIG. 6 as a voltage comparator. In the figure, a time scale is plotted on the horizontal axis and the number at pointing line indicates voltage or current In case shown FIG. 6, Vcc=3V, CL=50 pF, a constant voltage Vcc/2 is fed to the m input as a reference voltage and at the p input terminal a slowly changing triangular signal is supplied. The voltage waveform of the output terminal Vo1, Vo2, Vo3 and Vout are shown by “vo1”, “vo2”, “vo3” and “vout” respectively, the current waveform of the voltage supply Vcc and the transistor Q5 are shown by “vdd” and “q5”.

The p input is approaching to the reference voltage, both of vo1 and vo2 turn to lower level so that Q9 and Q10 turn on to flow a current and the voltage supply current increase from 580 nA to 22 μA.

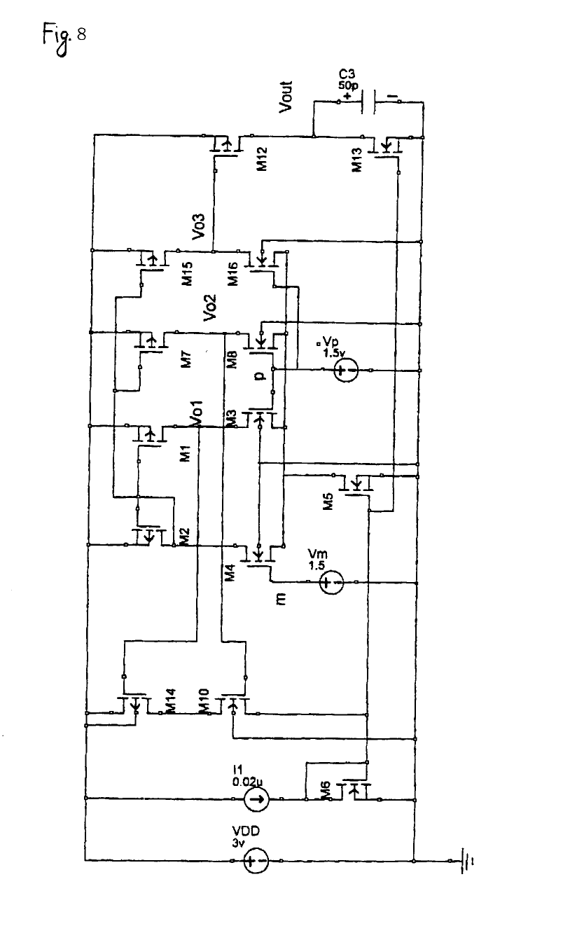

FIG. 8 is a circuit diagram showing a forth embodiment of the present invention corresponding to the claim-1. P-FETs are M1, M2, M7, M12, M14, and M15. N-FETs are M3, M4, M5, M8, M6, M10 and M13. Four input means M3, M4, M8 and M16 are connected to a bias current control circuit composed of M5.

Each of M1, M7 and M15 forms a current mirror coupled with P-FET M2 and is controlled under constant current as soon as possible. Therefore it is regarded as a current source and works as a high impedance load device in an amplifier. A source of current mirror M2 has diode connection then the drain output give a just small voltage swing, however a large voltage swing will appear at the output of M1, M7 and M15 when a current balance between a load device and a input device is collapsed.

The FET M1, M2, M7 and M15 are four load means and connected to the said four input means respectively. Each of M1 and M3, M2 and M4, M7 and M8, M15 and M16 composes an amplifier. All of four amplifiers are connected to the common “tail node”.

An inverting threshold of each amplifier can be calculated from the size ratio of the input device and load device according to previous equation (6).

The circuit in FIG. 8 has no boundary condition for M5 likewise the differential circuit in FIG. 1 or FIG. 4 since the mirror current of load device is generated separately from bias current generation circuit.

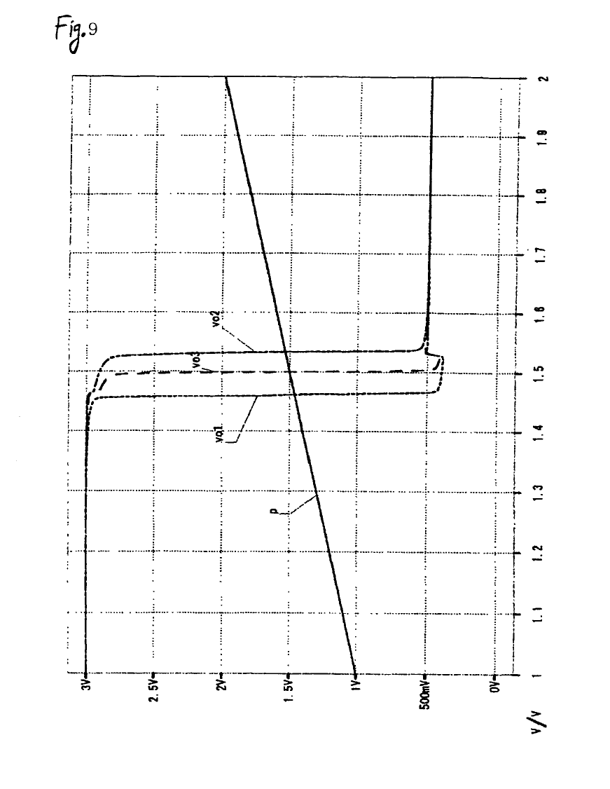

FIG. 9 is a simulated transfer characteristic of the circuit shown in FIG. 8.

A reference voltage Vm=1.5V is fed to the input m of M4. The size of M1 is smaller than that of M2 to give a minus theoretical offset on the output Vo1. While M7 is enlarged than that of M2 to have plus offset for the output Vo2. The output Vo3 has zero offset by making M15 same size as M2. A current conversion circuit consists of two different types of FET P-channel M10 and N-channel M14. The current conversion circuit draws a current during vo1=low and vo2=high and feed back to the bias current control circuit to increase the bias current.

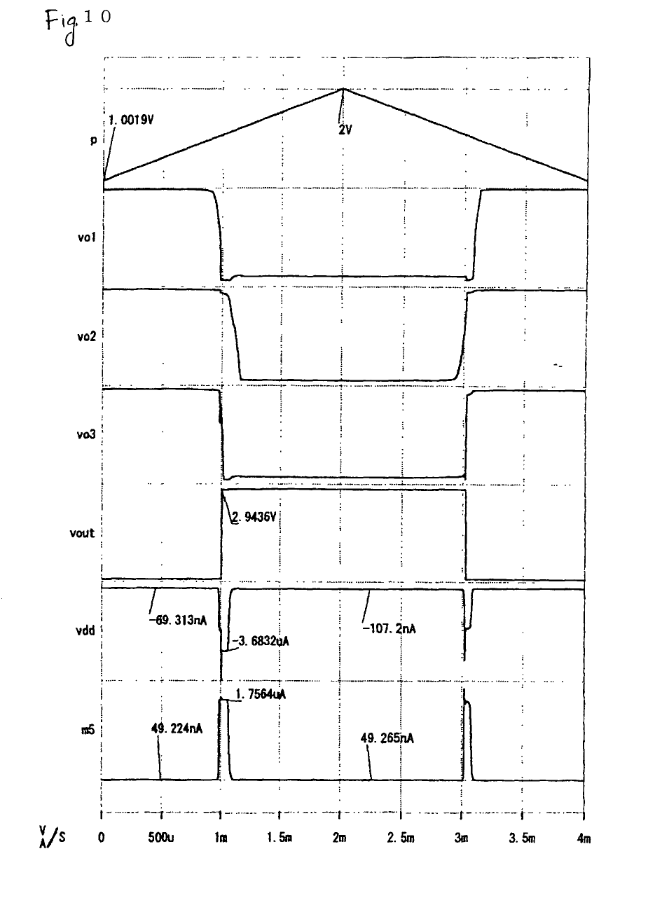

FIG. 10 is a simulated waveform diagram showing voltages and currents in respect to the circuit in FIG. 8 as a voltage comparator.

In the figure, a time scale is plotted on the horizontal axis and the number at pointing line indicates voltage or current. In case shown FIG. 10, VDD=3V, CL=50 pF, a constant voltage as VDD/2 is fed to the m input as a reference voltage and at the p input terminal a slowly changing triangular signal is fed. The voltage waveform of the output terminal Vo1, Vo2, Vo3 and Vout are shown by “vo1”, “vo2”, “vo3” and “vout” respectively, the current waveform of the voltage supply Vdd and the FET M5 are shown by “vdd” and “m5”.

The p input is approaching to the reference voltage, the output vo1 goes down to low level and the output vo2 keeps high level so that M14 and M10 turn on to flow a current and the bias current control circuit increase the bias current from 49 nA to 1.75 μA and then the whole circuit become activated. In the outside of activated status, the whole circuit is operated under very low current consumption, and the supply current vdd is measured to be 107 nA or 69 nA.

The output delay time is 27 μS at the fall transition, 9 μS at the rise transition that is fairy improved from the prior example.

A reference U.S. Pat. No. 5,381,054 has proposed similar circuit configuration as the present invention in FIG. 8. However, it is obvious again that the referenced circuit has different operation mechanism and function. Because its application is limited for a switches and resistive network in the claims, and as a tacit understanding all of its output have theoretical zero offset, and then the circuit cannot be applied for adaptive control by positive feed back current. Namely the present invention has similar circuit configuration as the referenced USP, it must be stressed again that its essence, effectiveness, and claims are quit different.

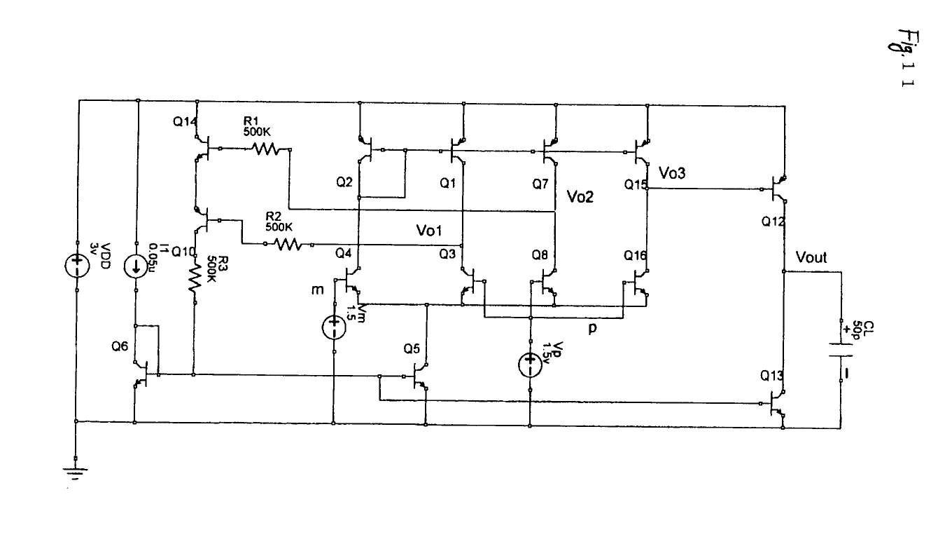

FIG. 11 is a circuit diagram showing a fifth embodiment of the present invention applied for a bipolar process or silicon germanium process, corresponding to the claim-1.

PNP transistors are Q1, Q2, Q7, Q12, Q14, and Q15. NPN transistors are Q3, Q4, Q5, Q8, Q6, Q10 and Q13. Four input devices Q3, Q4, Q8 and Q15 are connected to a bias current control circuit composed of Q5. Q1, Q2, Q7 and Q15 are four load devices and connected to the said four input device respectively. Each of Q1 and Q3, Q2 and Q4, Q7 and Q8, Q15 and Q16 composes an amplifier. All of four amplifiers are connected to a common “tail node”.

A current conversion circuit consists of different type transistors P-channel Q10 and N-channel Q14. The current conversion circuit draws a current during vo1=low and vo2=high and feed back to the bias current control circuit to increase the bias current.

NPN transistor Q13 and PNP transistor Q12 compose an output buffer that is connected to vo3 having no offset.

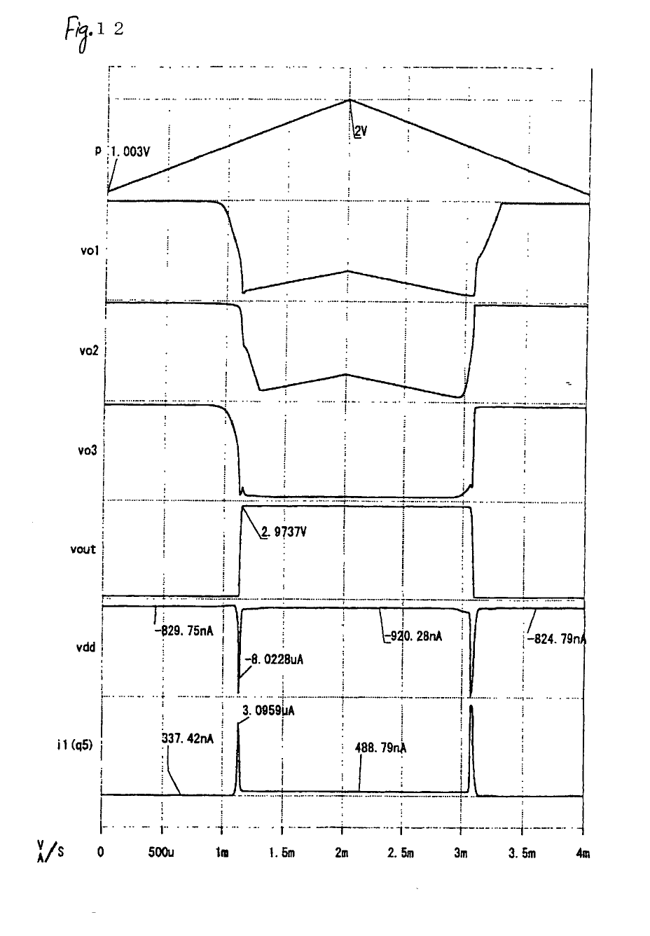

FIG. 12 is a simulated waveform diagram showing voltages and currents in respect to the circuit in FIG. 11 as a voltage comparator.

The p input is approaching to the reference voltage, both of the output Vo1 and the output vo2 turn to lower level so that Q9 and Q10 turn on to flow a current and the voltage supply current increase from 823 nA to 8 μA.

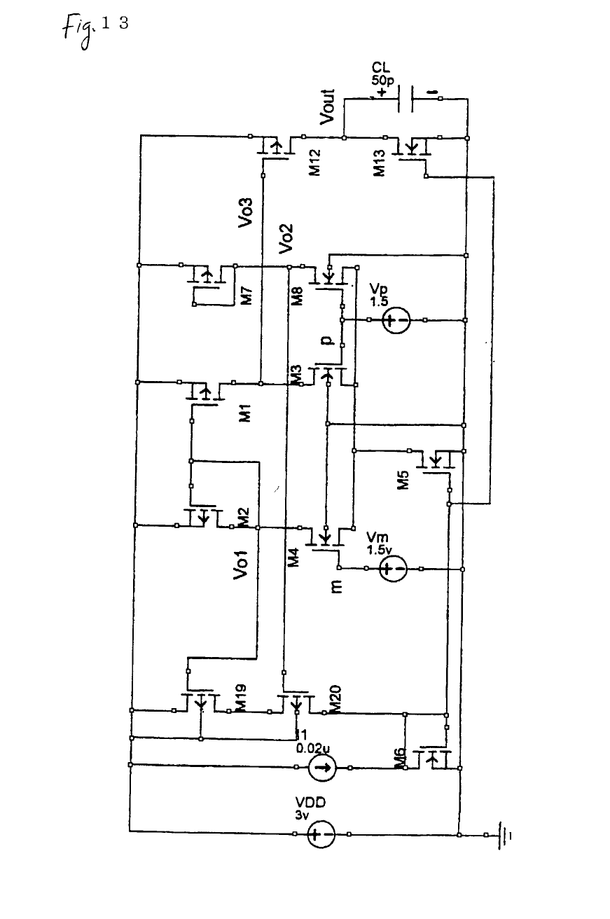

FIG. 13 is a circuit diagram showing a sixth embodiment of the present invention corresponding to the claim-1. P-FETs are M1, M2, M7, M12, M19, and M20. N-FETs are M3, M4, M5, M8, M6 and M13. Three input means M3, M4 and M8 are connected to a bias current control circuit composed of M5. M1, M2 and M7 are three load means and connected to the said three input device respectively. Each of M1 and M3, M2 and M4, M7 and M8 composes an amplifier. All of three amplifiers are connected to a common tail node.

In this embodiment, a theoretical offset is not designed by a size ratio between a load device and input device, but generated by positive feedback loop through a current conversion circuit. An output of M2 vo1 is connected to the gate of M19; an output of M7 vo2 is connected to the gate of M20. When the p input is equal to the reference input m, a current flow of M19 and M20 became peak, and therefore a feedback loop makes adaptive positive feedback operation just around the reference voltage. If the size of M1 and M3 is identical, the output vo3 has zero offset, accordingly the bias current is increased just around the inverting threshold of vo3.

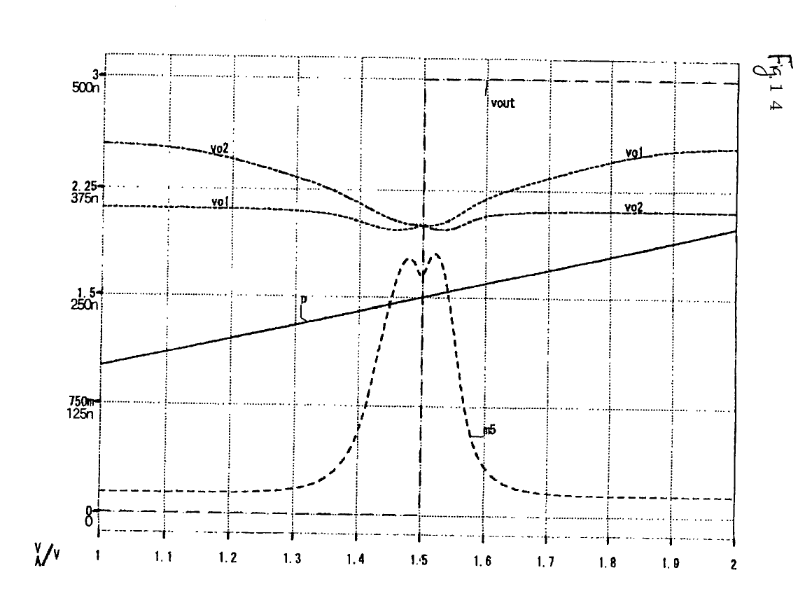

FIG. 14 is a simulated transfer characteristic of the circuit shown in FIG. 13.

In the figure, a voltage scale of the p input is plotted on the horizontal axis and the vertical axis shows voltage and current scale. In the case shown in FIG. 14, VDD=3V, CL=50 pF, a constant voltage as VDD/2 is fed to the m input.

The voltage curve of the output terminal Vo1, Vo2 and Vout are shown by “vo1”, “vo2” and “vout” respectively, the current characteristic curve of the FET M5 is shown by “m5”. The voltage characteristic curve of vo3 is omitted for easy observation. As shown in the figure, vo1 has plus offset about 100 mV, vo2 has minus offset −100 mV. The direction of offset is different from other embodiment case. The current of the bias current control circuit M5 swells between 1.4V and 1.6V. As shown in the figure, the current characteristic curve is symmetrical with respect to the reference voltage. This symmetry is attained by adjusted FET size of M20. The size of M20 is much larger than that of M19 to cancel a degradation of Gm caused by the back gate effect of M20. When the size of M19 and M20 is identical, the current characteristic curve is not symmetrical.

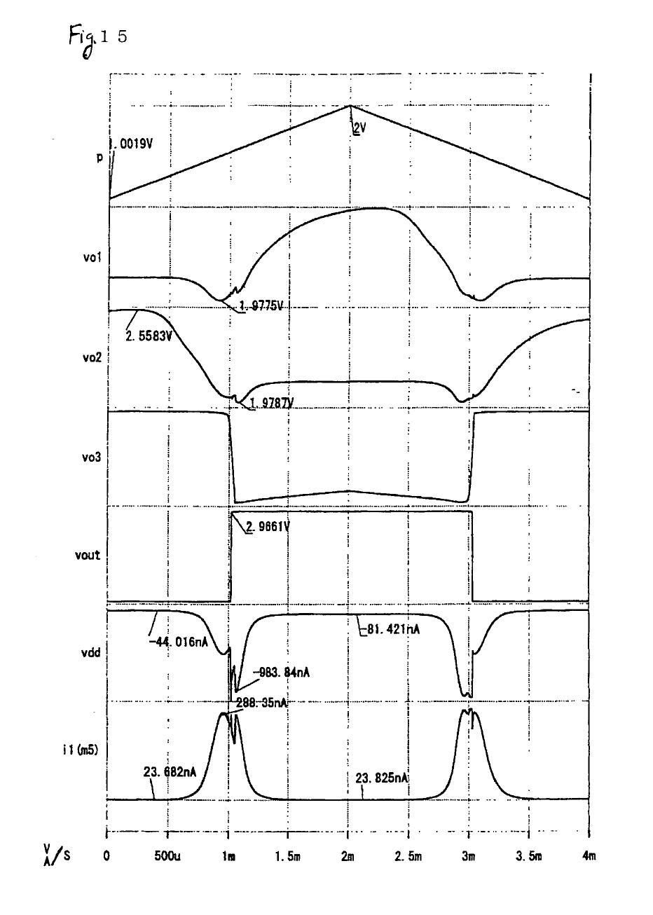

FIG. 15 is a simulated waveform diagram showing voltages and currents in respect to the circuit in FIG. 13 as a voltage comparator.

In the figure, a time scale is plotted on the horizontal axis and the number at pointing line indicates voltage or current. In case shown in the figure, VDD=3V, CL=50 pF, a constant voltage as VDD/2 is fed to the m input and at the p input terminal a slowly changing triangular signal is fed.

The voltage waveform of the output terminal Vo1, Vo2, Vo3 and Vout are shown by “vo1”, “vo2”, “vo3” and “vout” respectively, the current waveform of the voltage supply Vdd and the FET M5 are shown by “vdd” and “m5”.

The p input is approaching to the reference voltage, the output vo1 and the output vo2 drift to lower level so that M19 and M20 increase the current and the bias current control circuit M5 increases current from 23 nA to 288 nA and then the whole circuit become activated. In the outside of activated status, the whole circuit is operated under very low current consumption, and the supply current vdd is measured to be 44 nA or 81 nA.

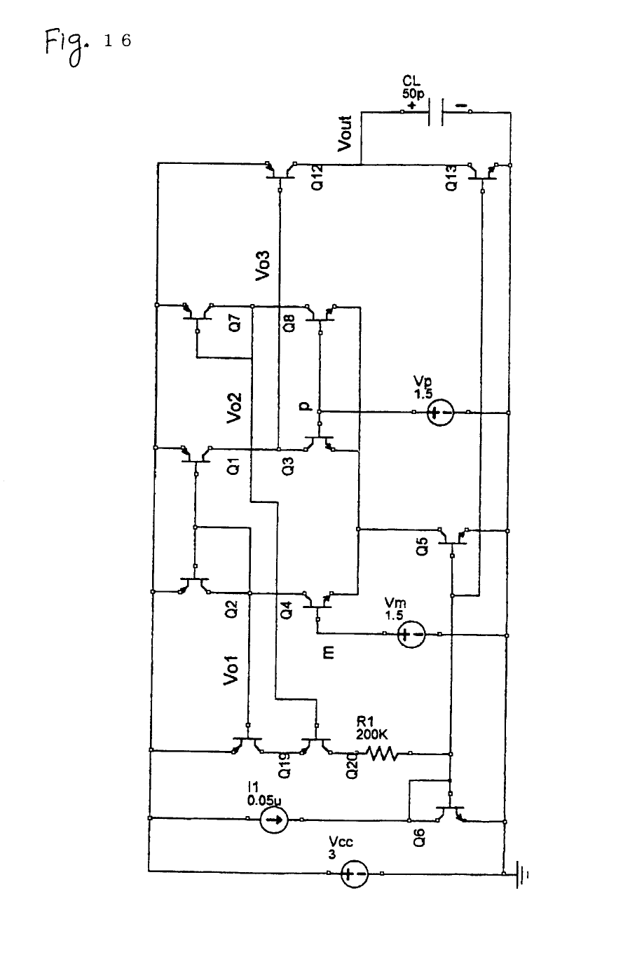

FIG. 16 is a circuit diagram showing a seventh embodiment of the present invention applied for a bipolar process or silicon germanium process, corresponding to the claim-1. A circuit configuration is analogical with the circuit in FIG. 13.

PNP transistors are Q1, Q2, Q7, Q12, Q19, and Q20. NPN transistors are Q3, Q4, Q5, Q8, Q6 and Q13. Three input means Q3, Q4 and Q8 are connected to a bias current control circuit composed of QM5. Q1, Q2 and Q7 are three load means and connected to the said three input means respectively. Each of Q1 and Q3, Q2 and Q4, Q7 and Q8 composes an amplifier. All of three amplifiers are connected to a common tail node.

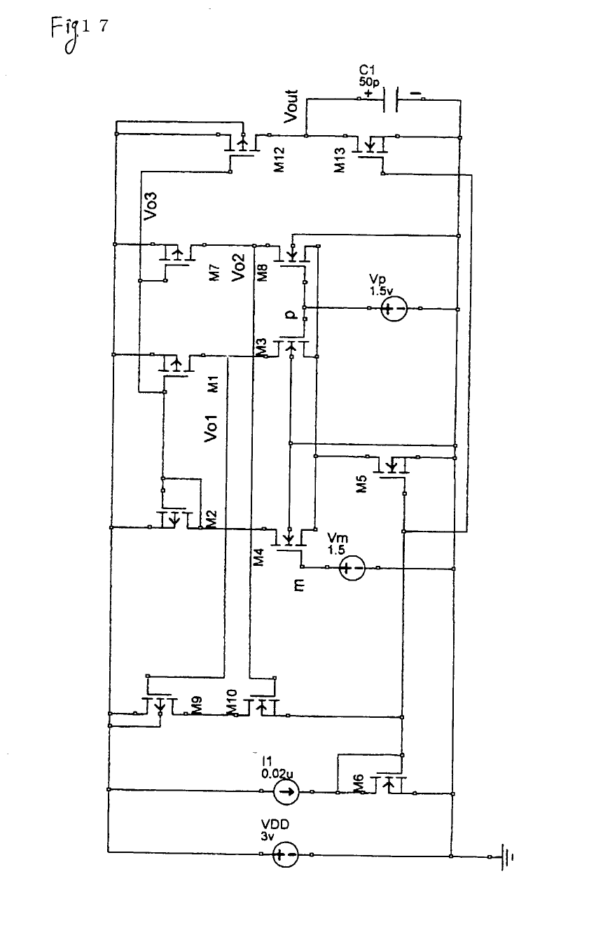

FIG. 17 is a circuit diagram showing an eighth embodiment of the present invention corresponding to the claim-1. P-FETs are M1, M2, M7, M9 and M12. N-FETs are M3, M4, M5, M8, M6 M10 and M13. Three input devices M3, M4 and M8 are connected to a bias current control circuit composed of M5. M1, M2 and M7 are three load devices and connected to the said three input device respectively. Each of M1 and M3, M2 and M4, M7 and M8 composes an amplifier. All of three amplifiers are connected to a common tail node.

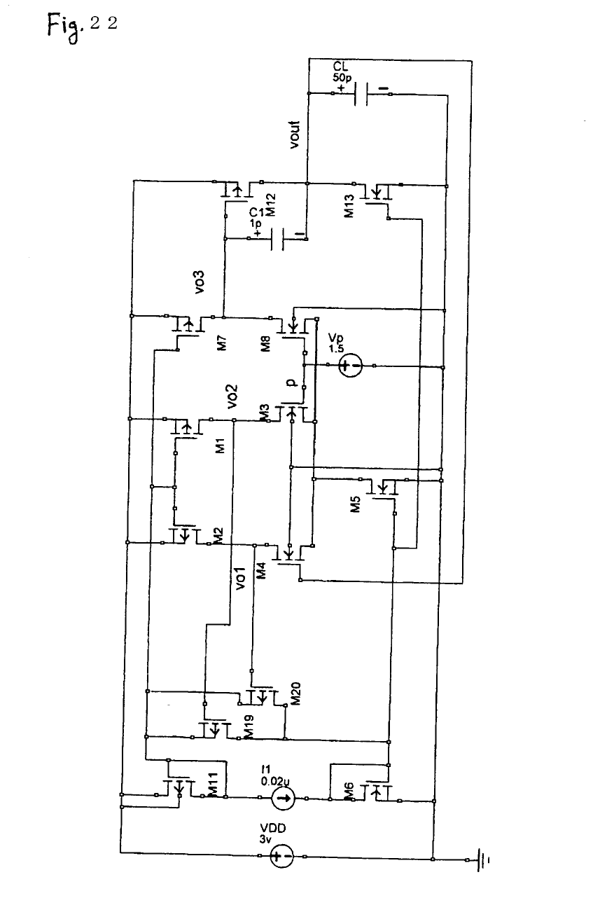

Previously mentioned embodiments are voltage comparators. Present invention is useful for a voltage follower circuit too. FIG. 22 is a circuit diagram showing a ninth embodiment of the present invention corresponding to the claim-1 and 2. It is applied as a voltage follower of which bias current is controlled or increased adaptively. P-FET M1, M2, M7, M12 and N-FET M3, M4, M5, M8, M13 and M6 have same connections as FIG. 4 excepting gate connection of M4. Major difference is a current conversion circuit. Two P-FET M19 and M20 compose a current conversion circuit are connected to the output Vo1 having minus offset and the output Vo2 having plus offset. Since two FET M19 and M20 is in parallel connection. N-FET M13 and P-FET M12 compose an output buffer that is connected to the output Vo3 having no offset.

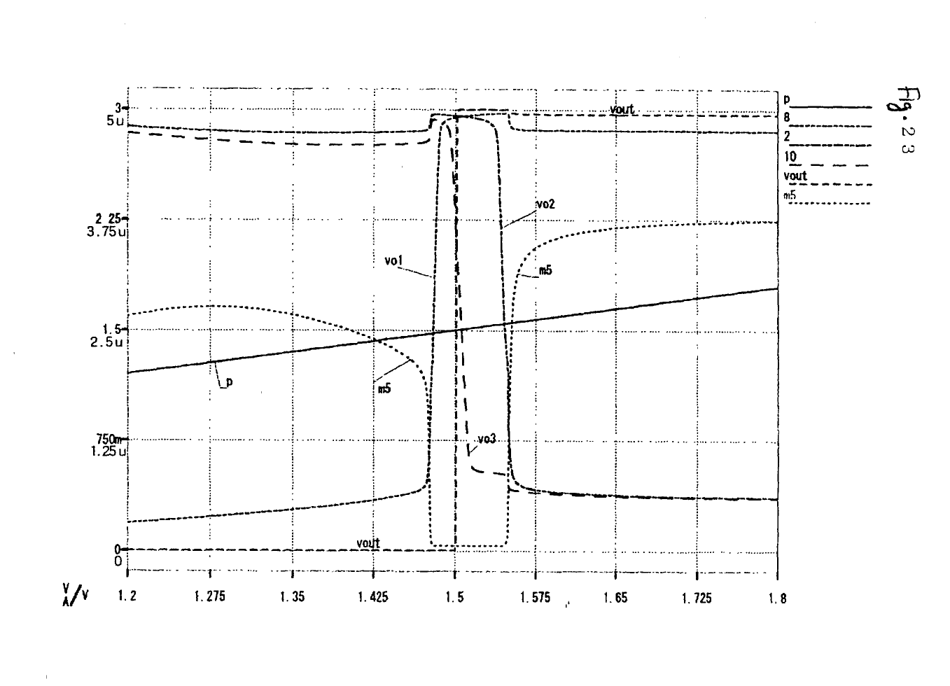

FIG. 23 is a simulated transfer characteristic of the circuit shown in FIG. 22.

In the figure, a voltage scale of the p input is plotted on the horizontal axis and the vertical axis shows voltage and current scale under the conditions as VDD=3V. CL=50 pF, a constant voltage as reference VDD/2 is fed to them input that is different connection from voltage follower operation.

The voltage curve of the output terminal Vo1, Vo2 and Vout are shown by “vo1”, “vo2” and “vout” respectively, the current characteristic curve of the voltage supply vdd and the FET M5 is shown by “vdd” and “m5” respectively. As shown in the figure, vo1 has minus offset about −20 mV, vo2 has plus offset about 40 mV. The current of the bias current control circuit M5 is dented in the vicinity of the reference voltage. It means that the bias current turns to minimum when voltage of the output Vout is equal to the p input signal in the voltage follower application. While the bias current is boosted when the output Vout does not follow the p-input signal. Call as balance pocket for the dented current area. The balance pocket is an equal state between the p input and the output Vout, which does not require big power consumption to keep the same. The width of balance pocket is varying from a few uV to few hundred mV depending upon applications. If the width of balance pocket is zero, a voltage follower circuit becomes unstable due to critical response for very small disturbance. In other word, the balance pocket created from the offset of vo1 and vo2 produces a delay time in the feed back loop to make the positive feed back stable. Either of vo1 or vo2 turns to low state, the current conversion circuit flows a current through the bias current generation circuit and then increases a current in the bias current controller M5 by positive feedback. In FIG. 23, the bias current of M5 increases from 55 nA in the vicinity of reference voltage to 3.7 μA. In the application such as a voltage follower or an error sense amplifier, the output is approximately equal to input during balanced state. It is well known that a little power consumption can keep the balanced state. The present invention realizes very low power in balanced state by the innovation of multi-input differential amplifier with intentional offset control.

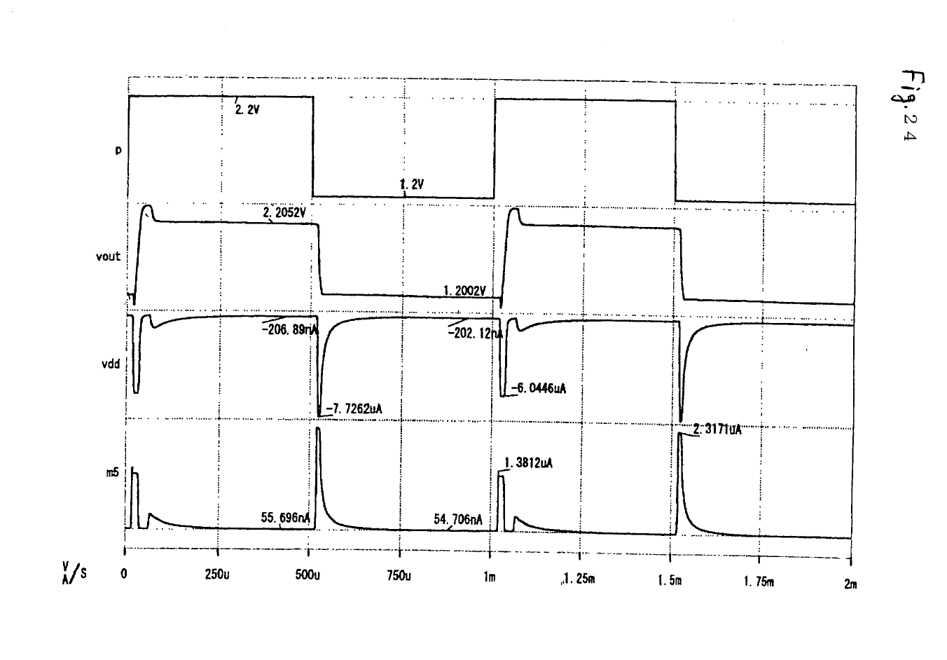

FIG. 24 is a simulated waveform diagram showing voltages and currents in respect to the circuit in FIG. 22 as a voltage follower. In the figure, a time scale is plotted on the horizontal axis and the number at pointing line indicates voltage or current. In case shown, VDD=3V, CL=50 pF, a pulse signal transiting between 1.2V and 2.2V is fed to the p input. The voltage waveform of the output terminal Vo1, Vo2, Vo3 and Vout are shown by “vo1”, “vo2 ”, “vo3” and “vout” respectively, the current waveform of the voltage supply Vdd and the FET M5 are shown by “vdd” and “m5”.

The whole circuit is operated under very low current consumption, and the supply current vdd is measured to be 206 nA at balanced state 7,7_A at transition. The output delay time is 48 μS at rise transition, 12 μS at fall transition that is fairy improved from the prior example 335 μS at fall transition under 588 nA idling current.

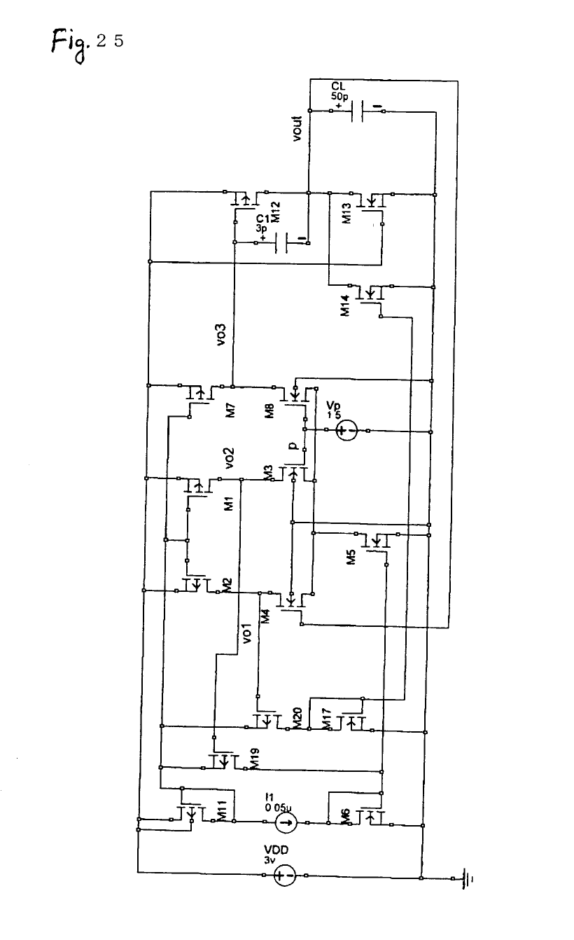

FIG. 25 is a circuit diagram showing a tenth embodiment of the present invention corresponding to the claim-1. It is applied as a voltage follower of which bias current is controlled or increased adaptively in the same way as FIG. 22. P-FET M1, M2, M7, M11, M12 and N-FET M3, M4, M5, M8, M13 and M6 have same connections as FIG. 22 excepting gate connection of M4. A current conversion circuit is consists of P-FET M19, M20 and N-FET M17 which is connected to the output Vo1 having minus offset and the output Vo2 having plus offset. N-FET M13, M14 and P-FET M12 compose an output buffer that is connected to the output Vo3 having zero offset. The gate of M14 is connected to the output of M17 in the current conversion circuit.

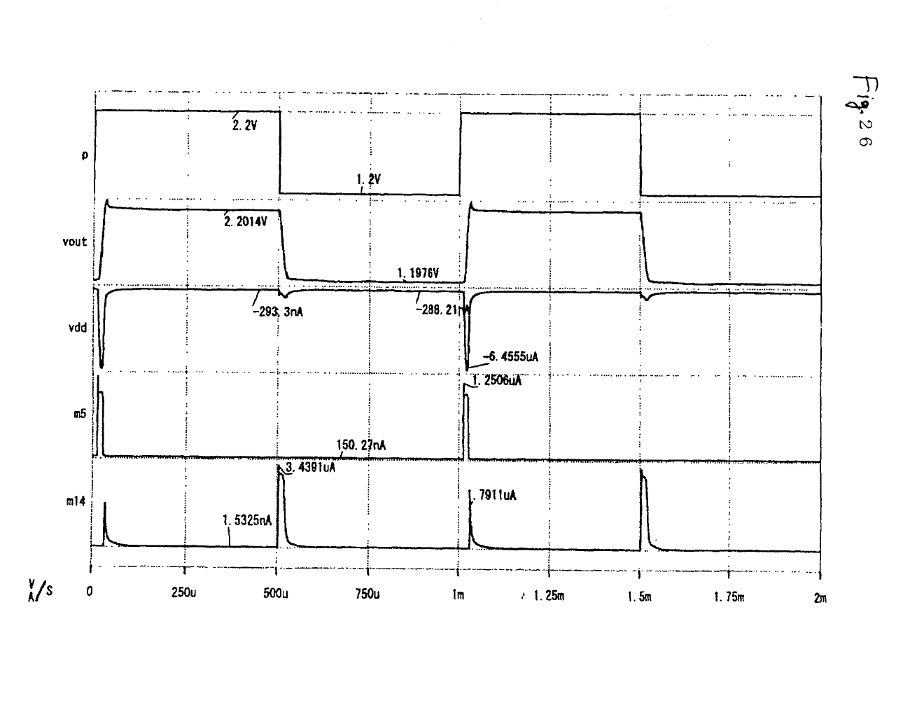

FIG. 26 is a simulated waveform diagram showing voltages and currents in respect to the circuit in FIG. 25 as a voltage follower. When the p input goes to high level, the output Vo1 transits to low side and M19 is biased forward to turn on and increase a current of the bias current control circuit. After rise-transition of the p input, the output Vout becomes same voltage as the p input and the idling current drops in a very little current state. When the p input goes to low level, the output vo2 transits to low side and M20 and M17 pass a current to turn on M14 and pull down the Vout until same level as the p input. In the figure the supply current vdd at balanced state is just 293 nA, and the delay time is 26 μS at rise transition and 20 μS at fall transition.

Thus not only simple parallel connection but also more complex combination is effective for a current conversion circuit.

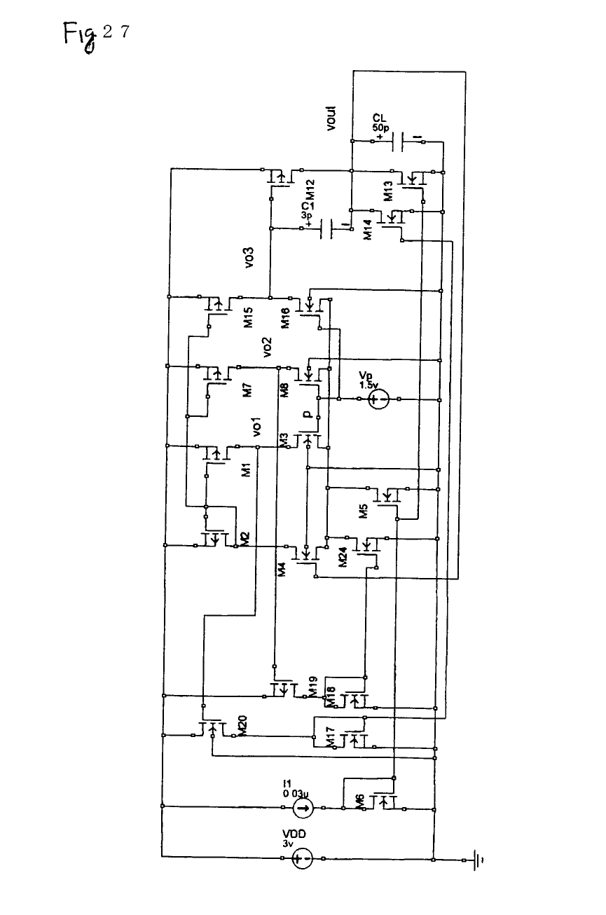

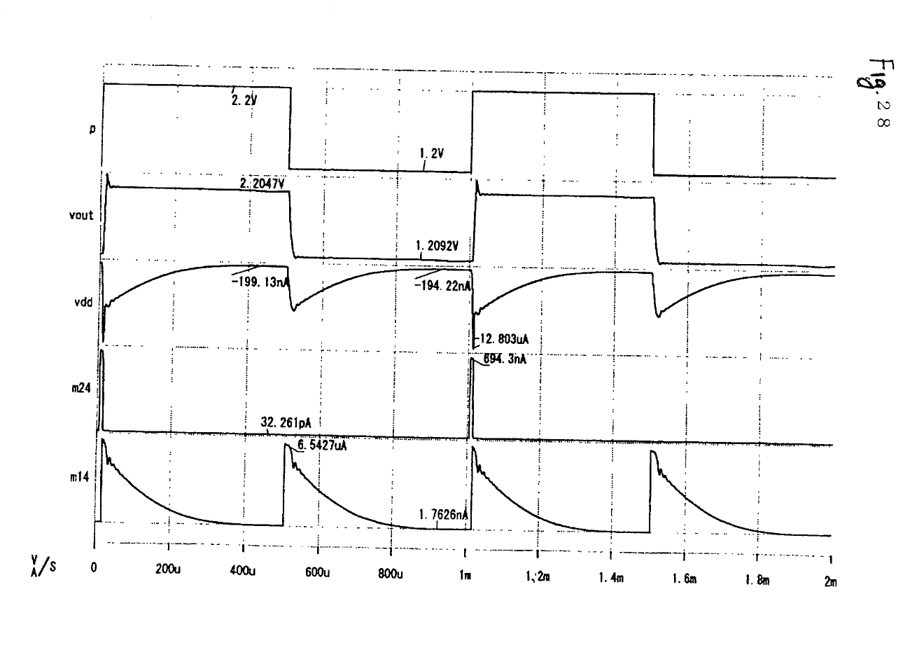

FIG. 27 is a circuit diagram showing an eleventh embodiment of the present invention corresponding to the claim-1. P-FET M19 and N-FET M20, M17, M18 compose a current conversion circuit. A bias current control circuit consists of N-FET M24 and M5. An output buffer has additional N-FET M14 of which gate is connected to the current conversion circuit. A part of four input differential amplifier is same as the circuit in FIG. 8 and the transfer characteristic is similar to the diagram in FIG. 9. FIG. 28 is a simulated waveform diagram showing voltages and currents in respect to the circuit in FIG. 27 as a voltage follower.

When the p input and vout are identical in voltage, the output vo1 is low and the vo2 is high level since M19 and M20 is off no current flows in the current conversion circuit. In FIG. 28 the current of supply current vdd is shown to be 199 nA or 194 nA. At the fall timing of the p input, the output vo1 goes to high level to turn M20 on and then M17 and M14 draw current to pull down the Vout until same level as the p input.

As shown in the figure FET M14 draws a peak current 6.5 μA and 1.7 nA at the steady state. At the rising edge of the p input, the output vo2 goes to low level to turn M19 on and then M18 and M24 draw mirrored current to increase the bias current of the differential circuit as a result the output of M15 and the output vout M12 response are accelerated. In the figure the current of M24 peaks at 693 nA. Due to a overshoot of the output vout M14 draws current at the same rising edge to pull back the overshoot.

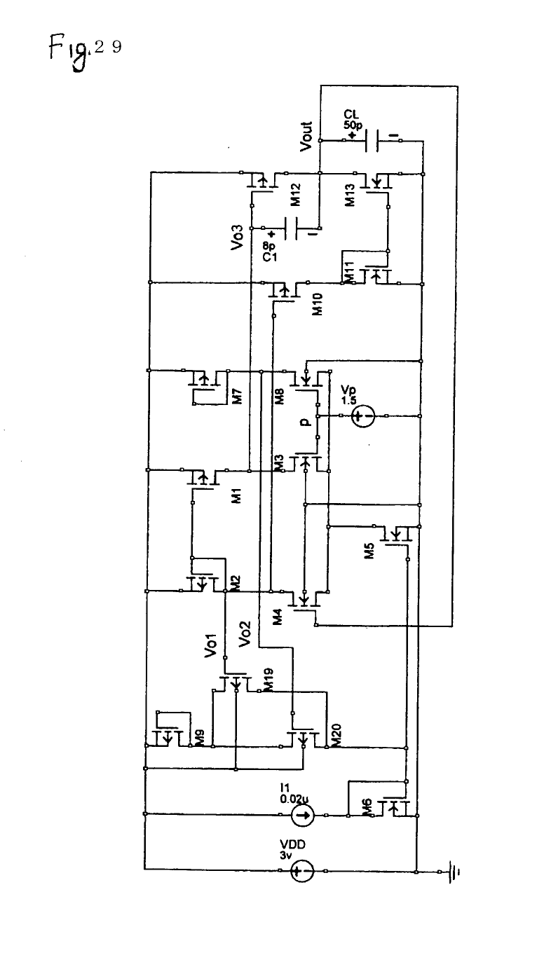

FIG. 29 is a voltage follower circuit diagram showing a twelfth embodiment of the present invention. An output buffer consists of N-FET M11, M13, P-FET M10 and M12. P-FET M19 and N-FET M20, M9 compose a current conversion circuit. M9 is inserted so as to decrease the bias current at the balance status between the input and the output.

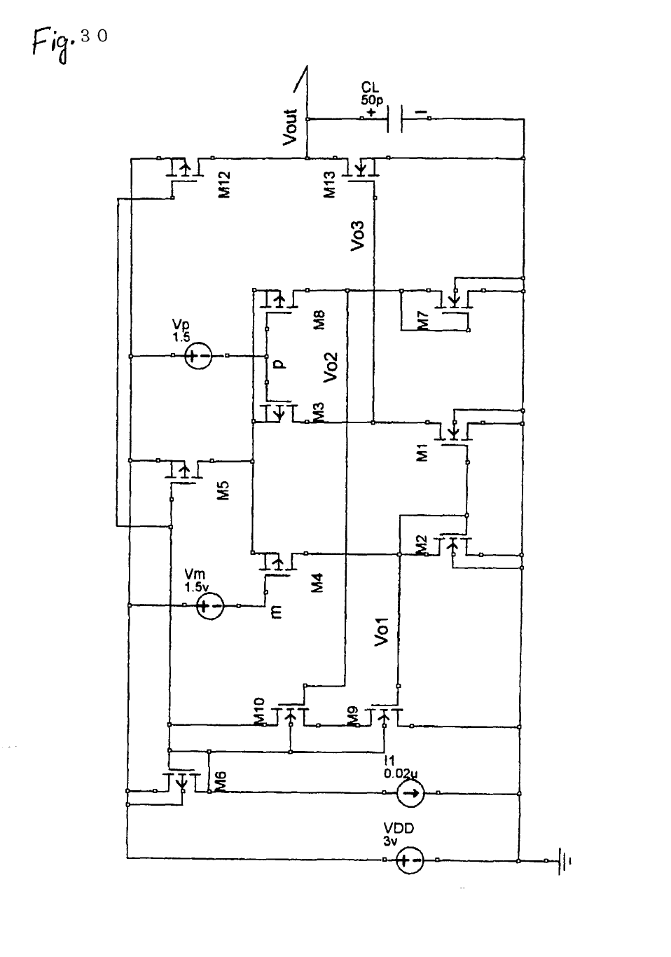

FIG. 30 is a circuit diagram shows an embodiment of the present invention. It is a modification from the circuit in FIG. 13. The circuit in FIG. 13 is P-FET input differential amplifier; FIG. 29 shows a N-FET input equivalent. Other embodiments also have such an equivalent conversion that is easily derivable although every one is not shown in figure. “FET” means not only MOS type but also junction type, TFT and, GaAs. Every kind of FET is applicable for the present invention.

For example a plus offset or a minus offset can be omitted for low-voltage detector application because a input does not pass away from a reference input.

And even though the claime-3 also is not shown, for instance, an output buffer can be deleted when a load is small and drivable from the output of differential amplifier.

Thus the differential amplifier comprising more than 3 amplifiers connected with common tail node and having various offsets is more excellent than every prior art in respect to number of element, design flexibility of offset, power saving and stability by balancing pocket and the usefulness of present invention is proven.

We are claiming:

1 A differential amplifier with three or more multi-inputs comprising;
a bias current control circuit, and n counts of input devices connected to the said bias current control circuit, and n counts of load devices connected to the said input devices and at least some of them compose a current mirror circuit, whereby said input devices and said load devices form n counts of amplifiers; of which at least one has no theoretical offset; and at least one has theoretical plus offset; and at least one has theoretical minus offset.

2 A differential amplifier with three or more multi-inputs comprising;
a bias current generator, and a bias current control circuit connected to the said bias current generator to make a mirror current, and N counts of input devices connected to the said bias current control circuit, and N counts of load devices connected to the said input devices and at least some of them compose a current mirror circuit, whereby said input devices and said load devices form N counts of amplifiers, and whereby the mirror current of the said bias control circuit is smaller than total sum of said mirror currents of the load devices, and larger than sum of said mirror currents of the load devices excluding maximum mirror current.

3 A differential amplifier with three or more multi-inputs comprising;
a current conversion circuit and a differential circuit claimed in 1 or 2;
whereby at least one of said amplifiers has predefined theoretical offset and is connected to the said current conversion circuit to modify the current of the bias control current according to said predefined theoretical offset.

4 A differential amplifier with three or more multi-inputs claimed in 1 or 2;
whereby said each input device or said each load device consists of plural active elements or passive elements.
